(19) United States
(12) Patent Application Publication
(10) Pub. No.: US 2011/0024874 A1
(43) Pub. Date: Feb. 3, 2011

(54) SEMICONDUCTOR DEVICE HAVING A 3D CAPACITOR AND METHOD FOR MANUFACTURING THE SAME

(75) Inventors: Cheol Hwan PARK, Gyeonggi-do (KR); Ho Jin CHO, Gyeonggi-do (KR); Dong Kyun LEE, Seoul (KR)

Correspondence Address: LADAS & PARRY LLP, 224 SOUTH MICHIGAN AVENUE, SUITE 1600, CHICAGO, IL, 60604, US

(73) Assignee: HYNIX SEMICONDUCTOR INC., Kyoungki-do (KR)

(21) Appl. No.: 12/647,621

(22) Filed: Dec. 28, 2009

(30) Foreign Application Priority Data
Jul. 30, 2009 (KR) 10-2009-0070036

(51) Int. Cl. H01L 29/92; H01L 21/02

(52) U.S. Cl. 257/532; 438/393; 257/E29.343; 257/E21.011

(57) ABSTRACT

A semiconductor device having a three-dimensional capacitor and a method for manufacturing the same is presented. The semiconductor device may have lower electrodes, a buffer layer, a dielectric layer, and an upper electrode. The lower electrodes are formed over a semiconductor substrate. The buffer layer is formed on sidewalls of the lower electrodes. The dielectric layer and an upper electrode are formed over semiconductor substrate including over the lower electrodes and the buffer layer. Accordingly, sufficient space between the lower electrodes can be secured. Furthermore, the lower electrodes can be each formed of a ruthenium layer and a titanium nitride layer and configured to have a pillar form. The dielectric layer may be composed of titanium dioxide.

### CROSS-REFERENCE TO RELATED APPLICATION

Priority to Korean patent application number 10-2009-0070036, filed on Jul. 30, 2009, which is incorporated by reference in its entirety, is claimed.

### BACKGROUND OF THE INVENTION

The present invention relates to a semiconductor device and a method for manufacturing the same.

Due to the demands for high degree of integration of semiconductor devices such in DRAM, the area occupied by these devices is reduced. However, there is a need to maintain or to even increase capacitance. A method of securing a sufficient cell capacitance within a limited area can include, for example, use a high dielectric (high-k) material as a dielectric layer, reduce the thickness of a dielectric layer, and/or increase the effective area of a lower electrode. Of these methods, the method of using a high dielectric (high-k) material requires material and time investments, such as the investment of new equipment, reliability of a dielectric layer, a need to verify mass production, and low temperature of a subsequent process. Accordingly, the method of increasing the effective area of a lower electrode is widely used in a process because it can use the existing dielectric layer and can be relatively easily implemented in the existing fabrication process facilities.

The method of increasing the effective area of a lower electrode includes a method of making three-dimensional the lower electrode in a cylinder form or a fin form; a method of growing hemi-spherical grain (HSG) in the lower electrode; and a method of increasing the height of the lower electrode. Of these methods, the method of growing HSG is problematic in that it becomes an obstruction when securing a certain level of a critical dimension (CD) between the lower electrodes and it often causes a bridge between the lower electrodes due to the peel-off of HSG. This makes the method of growing HSG difficult when manufacturing a semiconductor device having a design rule of 0.14 gill or less. Accordingly, to improve a cell capacitance, a method of making three-dimensional a lower electrode and increasing the height of the lower electrode is most often the preferable method. As an example of this method, a method of forming a lower electrode in a cylinder form or a stack form is widely known.

The cylinder-type or stack-type electrode has a structure that uses the exterior or both the exterior and the interior of the electrode. This type of structure is advantageous in that it can increase the area of the electrode. However, in a cylinder-type or stack-type electrode having an integrated one cylinder stack (OCS) structure, to secure a certain amount capacitance in a device, the height of the resultant lower electrode has to be increased. As a result, the lower electrode is prone to collapsing or breaking.

To solve the problem of the lower electrode from collapsing, it is necessary to secure space between the cylinder-type lower electrodes. Furthermore, to obtain the necessary characteristic of the cylinder-type lower electrode, there is a need to secure an internal space between the lower electrodes after sequentially depositing a dielectric material and an upper electrode. However, if a wide space between cells or a wide internal space of a cell is secured, then the CD of the cylinder-type lower electrode becomes insufficient. Thereby it makes it difficult to secure the requisite charge capacity of the lower electrode. To secure a sufficient charge capacity, a high-k material composition can be used. High-k materials are problematic in terms of very low productivity, lifting, etc.

### BRIEF SUMMARY OF THE INVENTION

An embodiment of the invention is directed to providing a semiconductor device and a method for manufacturing the same.

The method of manufacturing a semiconductor device comprises forming lower electrodes over a semiconductor substrate including lower electrode contact plugs, depositing a buffer layer on a surface of the lower electrodes, and forming a dielectric layer and an upper electrode over the entire surface including the buffer layer.

Each of the lower electrodes preferably has a pillar form.

Forming the lower electrodes preferably includes forming a buffer oxide layer, an etch-stop layer, a sacrificial insulating layer, and a hard mask layer over the entire surface including the lower electrode contact plugs, etching the hard mask layer, the sacrificial insulating layer, the etch-stop layer, and the buffer oxide layer to expose the lower electrode contact plugs and to thereby form the lower electrodes regions. A conductive layer is then deposited within the lower electrodes regions and subsequently etched until the sacrificial insulating layer is exposed.

The method preferably further comprises, after performing etching until the sacrificial insulating layer is exposed, etching the sacrificial insulating layer by performing a dip-out process, and cleaning the lower electrodes.

The sacrificial insulating layer preferably is formed of a single layer of a tetraethylorthosilicate (TEOS) layer or a dual layer of a phosphor silicate glass (PSG) layer and a TEOS layer.

Preferably, after forming the lower electrode regions, titanium (Ti) is deposited in the lower electrodes regions using a chemical vapor deposition (CVD) method, and titanium silicide is subsequently formed using a rapid thermal treatment.

The conductive layer preferably is made of any one selected from a group consisting of TiN, WN, TaN, Pt, Ru, a-Si, and a combinations thereof by using a CVD method or an atomic layer deposition (ALD) method.

The conductive layer to expose the sacrificial isolative layer is etched by using an etchback or chemical mechanical polishing (CMP) process.

The buffer layer preferably is a ruthenium (Ru) layer.

The buffer layer preferably is deposited to a thickness of between about 10 Å to 50 Å (Angstroms).

The dielectric layer preferably is made of titanium oxide (TiO₂) and is formed at a thickness of between about 30 Å to 150 Å.

The dielectric layer preferably is deposited using a CVD method or an ALD method.

The upper electrode preferably is made of titanium nitride (TiN) and is configured to have a dual layer of a CVD-TiN and PVD-TiN structure or a dual layer of an ALD-TIN and PVD-TiN structure.

The upper electrode is made of any one of Ru, Pt, TiAlN, TiSiN, TaN, and combinations thereof instead of TiN.

The method preferably further includes etching back the buffer layer after depositing the buffer layer.

The method preferably further includes, after depositing the buffer layer, changing the lower electrodes into lower electrodes each having a structure of a titanium nitride (TiN) layer, a ruthenium (Ru) layer, and a ruthenium oxide (RuO₂) layer by oxidizing the lower electrodes using an oxidization gas before depositing the dielectric layer.

According to another embodiment of the present invention, a semiconductor device comprises lower electrodes formed over a semiconductor substrate, a buffer layer formed on sidewalls of the lower electrodes, and a dielectric layer and an upper electrode formed over the entire surface including the buffer layer.

Each of the lower electrodes preferably has a pillar form.

The buffer layer preferably is a ruthenium (Ru) layer.

The buffer layer preferably is deposited to a thickness of 10 Å to 50 Å.

The dielectric layer preferably is made of titanium oxide (TiO₂) and is formed at a thickness of between about 30 Å to 150 Å.

The dielectric layer preferably is deposited using a CVD method or an ALD method.

The upper electrode preferably is made of titanium nitride (TiN) and is configured to have a dual layer of a CVD-TiN and PVD-TiN structure or a dual layer of an ALD-TIN and PVD-TiN structure.

The upper electrode preferably is made of any one of Ru, Pt, TiAlN, TiSiN, TaN, and combinations thereof instead of TiN.

### BRIEF DESCRIPTION OF THE DRAWINGS

FIGS. 1a to 1i are cross-sectional views illustrating a semiconductor device and a method of manufacturing the same according to an embodiment of the present invention.

### DESCRIPTION OF EMBODIMENT

Hereinafter, an embodiment of the present invention is described in detail with reference to the accompanying drawings.

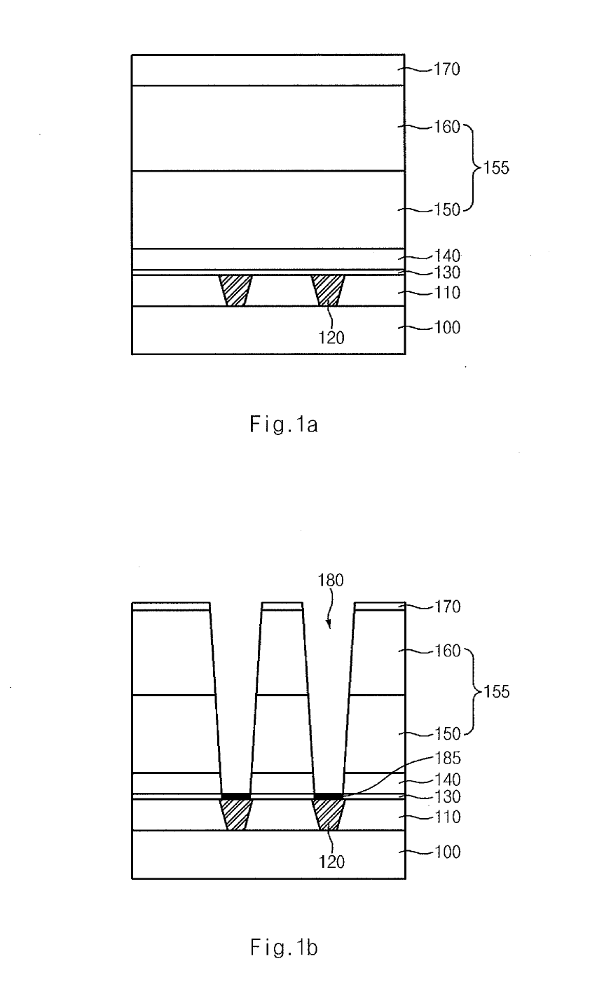

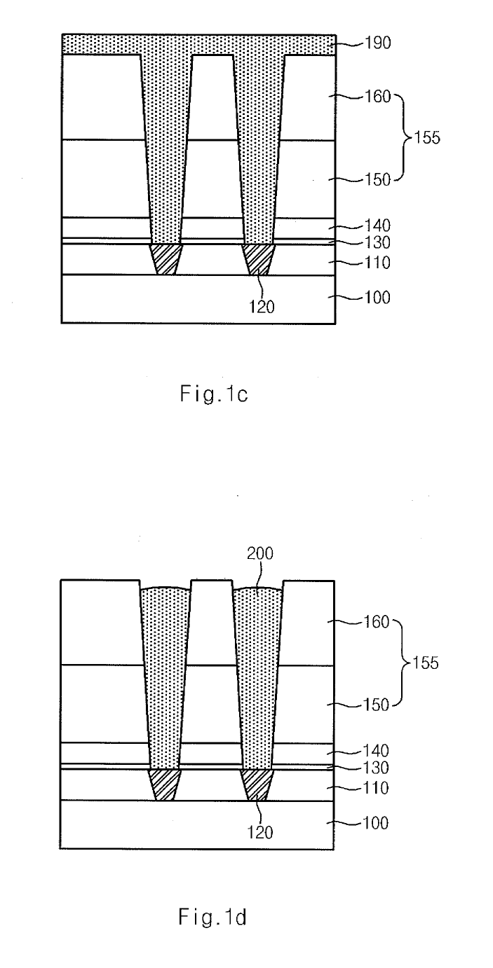

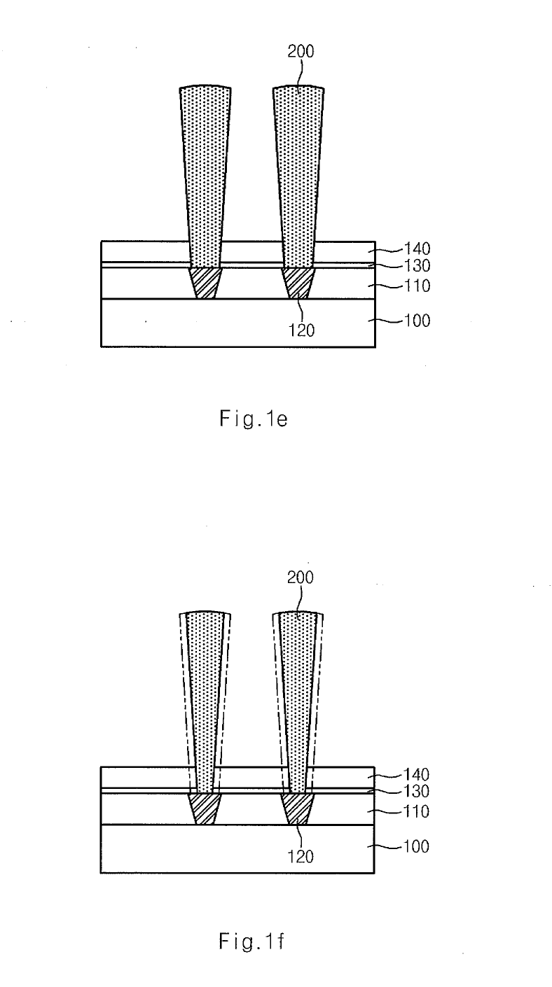

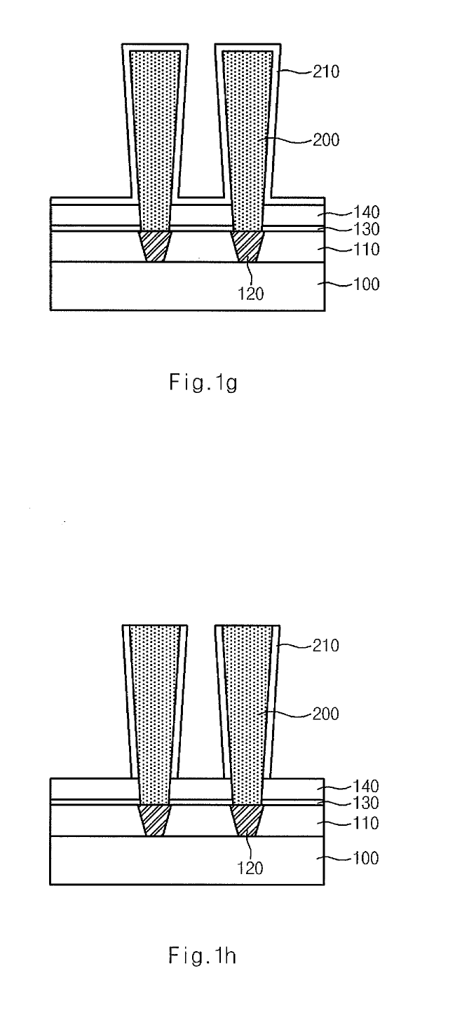

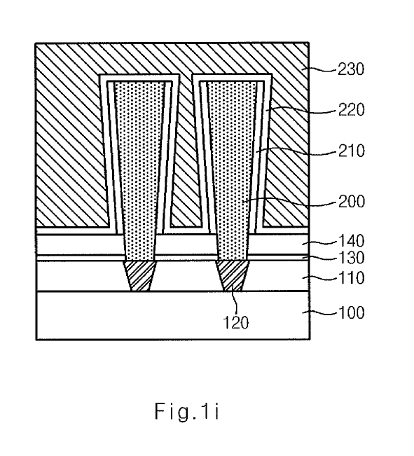

FIGS. 1a to 1i are cross-sectional views illustrating a semiconductor device and a method for manufacturing the same according to an embodiment of the present invention. It is understood herein that the drawings are not necessarily to scale and in some instances proportions may have been exaggerated in order to more clearly depict certain features of the invention.

Referring to FIG. 1a, a dielectric interlayer 110 is formed on a semiconductor substrate 100. The dielectric interlayer 110 is etched to form lower electrode contact plugs 120. A buffer oxide layer 130 and an etch-stop layer 140 are sequentially stacked over the entire surface including the lower electrode contact plugs 120. Here, the etch-stop layer 140 is preferably a nitride layer.

A first sacrificial insulating layer 155 is formed on the etch-stop layer 140. One variation of the first sacrificial insulating layer 155 comprises a stack structure composed of a phosphor silicate glass (PSG) layer 150 and a tetraethylorthosilicate (TEOS) layer 160. Another variation is that the first sacrificial insulating layer 155 may comprise a is single layer of the TEOS layer.

A hard mask layer 170 is formed on the first sacrificial insulating layer 155.

Referring to FIG. 1b, after forming a photoresist layer on the hard mask layer 170, photoresist patterns (not shown) are formed, by using well known exposure and development processes, using a lower electrode regions mask. The hard mask layer 170, the first sacrificial insulating layer 155, the etch-stop layer 140, and the buffer oxide layer 130 are etched using the photoresist patterns as a mask until the lower electrode contact plugs 120 are exposed, thereby forming lower electrode regions 180.

In order to minimize contact resistance between the lower electrode regions 180 and the respective lower electrode contact plugs 120, titanium (Ti) is deposited in the lower electrode regions using a chemical vapor deposition (CVD) method. This is followed by a rapid thermal treatment which forms titanium silicide 185 between the lower electrode regions 180 and the respective lower electrode contact plugs 120.

Referring to FIGS. 1c, and 1d, the lower electrode regions 180 is then subsequently filled in with a conductive layer 190. The conductive layer preferably is made of any one selected from the group consisting of TiN, WN, TaN, Pt, Ru, a-c Si, and combinations thereof. The conductive layer 190 may be deposited using a CVD method or an atomic layer deposition (ALD) method.

The conductive layer (for example, TiN layer) 190 is then etched to expose the TEOS layer 160 which results in forming the lower electrodes 200. Each of the lower electrodes 200 preferably has a pillar form. When etching the TiN layer 190, etchback or chemical mechanical polishing (CMP) can be used.

Referring to FIG. 1e, the first sacrificial insulating layer 155 is then subsequently removed by performing a dip-out process. The dip-out process preferably is a wet dip-out process.

Referring to FIG. 1f, a cleaning process is then performed on the exposed lower electrodes 200. The cleaning process is performed in order to secure space between the lower electrodes 200 and preferably is performed using a Pirana cleaning process comprising a mixture of sulfuric acid and peroxide.

Referring to FIGS. 1g, and 1h, a buffer layer 210 is next deposited over the entire surface including the lower electrodes 200 using an ALD method. The buffer layer 210 preferably comprises a ruthenium (Ru) layer. The buffer layer 210 preferably is deposited at a thickness of to between about 10 Å to 50 Å.

The buffer layer 210 is etched back to expose a top surface of the lower electrodes 200 and a top surface of the etch-stop layer 140.

Next, the lower electrodes 200 and the buffer layer 210 are oxidized using an oxidization gas such that they are changed into a structure of a titanium nitride (TiN) layer, a ruthenium (Ru) layer, and a ruthenium oxide (RuO₂) layer. Such a changed structure has a composition of a high-k constant because the TiN layer, the Ru layer, and the RuO₂ layer have the same crystallization state as a dielectric layer 220 deposited in a subsequent process.

Referring to FIG. 1i, the dielectric layer 220 is formed over the entire surface including the buffer layer 210. Here, the dielectric layer 220 preferably is made of TiO₂. The dielectric layer 220 preferably is formed at a thickness of between about 30 Å to 150 Å. An upper electrode 230 is formed over the entire surface including the dielectric layer 220. The upper electrode 230 preferably has a dual layer of CVD-TiN and PVD-TiN. Alternatively, the upper electrode 230 may have a dual layer of ALD-TiN and PVD-TIN. Furthermore, the upper electrode 230 may be made of Ru, Pt, TiAlN, TiSiN, or TaN instead of titanium nitride (TiN).

As described above, according to the present invention, after the dip-out process, the lower electrodes are cleaned. Accordingly, sufficient space between the lower electrodes can be secured. Furthermore, the dual lower electrodes each formed of the Ru layer and the TiN layer and configured to have a pillar form and the dielectric layer made of TiO₂ are deposited. Accordingly, there is an advantage in that the electrical characteristic of the lower electrodes can be improved.

The above exemplary embodiments of the present invention are understood to be illustrative and not limitative. Accordingly, various other alternatives, variations and equivalents are possible within the scope of the present invention. The invention is understood to be not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
forming lower electrodes over a semiconductor substrate including lower electrode contact plugs;
depositing a buffer layer on a surface of the lower electrodes; and
forming a dielectric layer and an upper electrode over an entire surface including the buffer layer.

2. The method according to claim 1, wherein each of the lower electrodes has a pillar form.

3. The method according to claim 1, wherein the step of forming lower electrodes includes:
forming a buffer oxide layer, an etch-stop layer, a sacrificial insulating layer, and a hard mask layer over the semiconductor substrate including the lower electrode contact plugs;
etching the hard mask layer, the sacrificial insulating layer, the etch-stop layer, and the buffer oxide layer to expose the lower electrode contact plugs and to form lower electrodes regions; and
depositing a conductive layer within the lower electrodes regions and etching the conductive layer until the sacrificial insulating layer is exposed.

4. The method according to claim 3, further comprising:
etching away the sacrificial insulating layer by performing a dip-out process; and
cleaning the lower electrodes.

5. The method according to claim 4, wherein cleaning the lower electrodes is to etch slightly the lower electrodes to reduce CD (Critical Dimension) of the lower electrodes

6. The method according to claim 3, wherein the sacrificial insulating layer comprises a single layer of a tetraethylorthosilicate (TEOS) layer or a dual layer of a phosphor silicate glass (PSG) layer and an upper TEOS layer.

7. The method according to claim 3, further comprising:
depositing, after forming the lower electrode regions, titanium (Ti) in the lower electrodes regions using a chemical vapor deposition (CVD) method; and
forming titanium silicide from the deposited Ti in the lower electrode regions by using a rapid thermal treatment.

8. The method according to claim 3, wherein the conductive layer is made of any one selected from a group consisting of TiN, WN, TaN, Pt, Ru, a-Si, and a combination thereof by using a CVD method or an atomic layer deposition (ALD) method.

9. The method according to claim 3, wherein the conductive layer is etched by using an etchback or chemical mechanical polishing (CMP) process.

10. The method according to claim 1, wherein the buffer layer comprises a ruthenium (Ru) layer.

11. The method according to claim 1, wherein the buffer layer is deposited at a thickness of between about 10 Å to 50 Å.

12. The method according to claim 1, wherein the dielectric layer comprises titanium oxide (TiO₂) and is formed at a thickness of between about 30 Å to 150 Å.

13. The method according to claim 1, wherein the dielectric layer is deposited using a CVD method or an ALD method.

14. The method according to claim 1, wherein the upper electrode comprises titanium nitride (TiN) and is configured to have a dual layer composed of a CVD-TiN and PVD-TiN structure or a dual layer composed of an ALD-TIN and PVD-TiN structure.

15. The method according to claim 1, wherein the upper electrode is made of any one of Ru, Pt, TiAlN, TiSiN, TaN, and combinations thereof.

16. The method according to claim 1, further comprising etching back the buffer layer after depositing the buffer layer.

17. The method according to claim 1, further comprising oxidizing, before depositing the dielectric layer, the lower electrodes to change a structure of a titanium nitride (TiN) layer, a ruthenium (Ru) layer, and a ruthenium oxide (RuO₂) layer of the lower electrodes.

18. A semiconductor device comprising:
lower electrodes formed over a semiconductor substrate;
a buffer layer formed on sidewalls of the lower electrodes; and
a dielectric layer and an upper electrode formed over semiconductor substrate including the lower electrodes and the buffer layer.

19. The semiconductor device according to claim 18, wherein each of the lower electrodes has a pillar form.

20. The semiconductor device according to claim 18, wherein the buffer layer comprises a ruthenium (Ru) layer.

21. The semiconductor device according to claim 18, wherein the buffer layer is deposited at a thickness of between about 10 Å to 50 Å

22. The semiconductor device according to claim 18, wherein the dielectric layer comprises titanium oxide (TiO₂) and is formed at a thickness of between about 30 Å to 150 Å.

23. The semiconductor device according to claim 18, wherein the dielectric layer is deposited using a CVD method or an ALD method.

24. The semiconductor device according to claim 18, wherein the upper electrode comprises titanium nitride (TiN) and is configured to have a dual layer of a CVD-TiN and PVD-TiN structure or a dual layer of an ALD-TIN and PVD-TiN structure.

25. The semiconductor device according to claim 18, wherein the upper electrode is comprises any one of Ru, Pt, TiAlN, TiSiN, TaN, and a combinations thereof.
